(19) United States
(12) Patent Application Publication
(10) Pub. No.: US 2024/0017990 A1
(43) Pub. Date: Jan. 18, 2024

(54) METHODS OF SEPARATING GOOD PROBE STRUCTURES FROM DEFECTIVE PROBE STRUCTURES IN AN ELECTROCHEMICAL FABRICATION SYSTEM

(71) Applicant: Microfabrica Inc., Van Nuys, CA (US)

(72) Inventors: Duy P. Le, San Francisco, CA (US); Rulon J. Larsen, Colorado Springs, CO (US); Jeffrey A. Thompson, Van Nuys, CA (US); Uri Frodis, Los Angeles, CA (US); Dale S. McPherson, Kissimmee, FL (US); Kleun Kim, Los Angeles, CA (US); Mahmood Samiee, Glendale, CA (US); Nina C. Levy, Los Angeles, CA (US); Dennis R. Smalley, Newhall, CA (US)

(21) Appl. No.: 18/301,162

(22) Filed: Apr. 14, 2023

Related U.S. Application Data
(63) Continuation of application No. 15/925,613, filed on Mar. 19, 2018, now abandoned.
Application No. 15/925,613 is a continuation of application No. 14/872,033, filed on Sep. 30, 2015, now abandoned.
Application No. 14/872,033 is a continuation-in-part of application No. 14/043,670, filed on Oct. 1, 2013, now abandoned.
(60) Provisional application No. 62/058,052, filed on Sep. 30, 2014.
(60) Provisional application No. 61/712,822, filed on Oct. 12, 2012.

(51) Int. Cl. B81C 99/00

(52) U.S. Cl. CPC B81C 99/003; B81C 99/004; B81C 2201/0105; B81C 2201/013

(57) ABSTRACT

Electronic test probes formed in a batch have a plurality of multi-material layers wherein at least one of the materials is a sacrificial material and at least one other material is a structural material. Successfully formed or good test probes are separated from unsuccessfully formed or bad test probes

### BACKGROUND OF THE INVENTION

An electrochemical deposition process for forming multilayer structures may be carried out in a number of different ways. In one form, this process involves three separate operations during the formation of each layer of the structure that is to be formed. The first step is selectively depositing at least one material by electrodeposition upon one or more desired regions of a substrate. Typically this material is either a structural material or a sacrificial material. Then, at least one additional material is blanket deposited by electrodeposition so that the additional deposit covers both the regions that were previously selectively deposited onto, and the regions of the substrate that did not receive any previously applied selective depositions. Typically this material is the other of a structural material or a sacrificial material. The final step is planarizing the materials deposited during the first and second operations to produce a smoothed surface of a first layer of desired thickness having at least one region containing the at least one material and at least one region containing at least the one additional material.

After formation of the first layer, one or more additional layers may be formed adjacent to an immediately preceding layer and adhered to the smoothed surface of that preceding layer. These additional layers are formed by repeating the first through third operations one or more times wherein the formation of each subsequent layer treats the previously formed layers and the initial substrate as a new and thickening substrate.

Once the formation of all layers has been completed, at least a portion of at least one of the materials deposited is generally removed by an etching process to expose or release the three-dimensional structure that was intended to be formed. The removed material is a sacrificial material while the material that forms part of the desired structure is a structural material.

One method of performing the selective electrodeposition involved in the first operation is by conformable contact mask plating. In this type of plating, one or more conformable contact (CC) masks are first formed. The CC masks include a support structure onto which a patterned conformable dielectric material is adhered or formed. The conformable material for each mask is shaped in accordance with a particular cross-section of material to be plated (the pattern of conformable material is complementary to the pattern of material to be deposited). In such a process at least one CC mask is used for each unique cross-sectional pattern that is to be plated.

In preparation for performing the selective deposition of the first operation, the conformable portion of the CC mask is placed in registration with and pressed against a selected portion of (1) the substrate, (2) a previously formed layer, or (3) a previously deposited portion of a layer on which deposition is to occur. The pressing together of the CC mask and relevant substrate occur in such a way that all openings, in the conformable portions of the CC mask contain plating solution. The conformable material of the CC mask that contacts the substrate acts as a barrier to electrodeposition while the openings in the CC mask that are filled with electroplating solution act as pathways for transferring material from an anode (e.g. the CC mask support) to the non-contacted portions of the substrate (which act as a cathode during the plating operation) when an appropriate potential and/or current are supplied.

An example of a CC mask and CC mask plating are shown in FIGS. 1A-1C. FIG. 1A shows a side view of a CC mask 8 consisting of a conformable or deformable (e.g. elastomeric) insulator 10 patterned on an anode 12. The anode has two functions. One is as a supporting material for the patterned insulator 10 to maintain its integrity and alignment since the pattern may be topologically complex (e.g., involving isolated “islands” of insulator material). The other function is as an anode for the electroplating operation. FIG. 1A also depicts a substrate 6, separated from mask 8, onto which material will be deposited during the process of forming a layer. CC mask plating selectively deposits material 22 onto substrate 6 by simply pressing the insulator against the substrate then electrodepositing material through apertures 26a and 26b in the insulator as shown in FIG. 1B. After deposition, the CC mask is separated, preferably non-destructively, from the substrate 6 as shown in FIG. 1C.

Another example of a CC mask and CC mask plating is shown in FIGS. 1D-1G. FIG. 1D shows an anode 12′ separated from a mask 8′ that includes a patterned conformable material 10′ and a support structure 20. FIG. 1D also depicts substrate 6 separated from the mask 8′. FIG. 1E illustrates the mask 8′ being brought into contact with the substrate 6. FIG. 1F illustrates the deposit 22′ that results from conducting a current from the anode 12′ to the substrate 6. FIG. 1G illustrates the deposit 22′ on substrate 6 after separation from mask 8′. In this example, an appropriate electrolyte is located between the substrate 6 and the anode 12′ and a current of ions coming from one or both of the solution and the anode are conducted through the opening in the mask to the substrate where material is deposited. This type of mask may be referred to as an anodeless INSTANT MASK™ (AIM) or as an anodeless conformable contact (ACC) mask.

Unlike through-mask plating, CC mask plating allows CC masks to be formed completely separate from the substrate on which plating is to occur (e.g. separate from a three-dimensional (3D) structure that is being formed). CC masks may be formed in a variety of ways, for example, using a photolithographic process. All masks can be generated simultaneously, e.g. prior to structure fabrication rather than during it. This separation makes possible a simple, low-cost, automated, self-contained, and internally-clean “desktop factory” that can be installed almost anywhere to fabricate 3D structures, leaving any required clean room processes, such as photolithography to be performed by service bureaus or the like.

An example of the electrochemical fabrication process discussed above is illustrated in FIGS. 2A-2F. These figures show that the process involves deposition of a first material 2 which is a sacrificial material and a second material 4 which is a structural material. The CC mask 8, in this example, includes a patterned conformable material (e.g. an elastomeric dielectric material) 10 and a support 12 which is made from deposition material 2. The conformal portion of the CC mask is pressed against substrate 6 with a plating solution 14 located within the openings 16 in the conformable material 10. An electric current, from power supply 18, is then passed through the plating solution 14 via (a) support 12 which doubles as an anode and (b) substrate 6 which doubles as a cathode. FIG. 2A illustrates that the passing of current causes material 2 within the plating solution and material 2 from the anode 12 to be selectively transferred to and plated on the substrate 6. After electroplating the first deposition material 2 onto the substrate 6 using CC mask 8, the CC mask 8 is removed as shown in FIG. 2B. FIG. 2C depicts the second deposition material 4 as having been blanket-deposited (i.e. non-selectively deposited) over the previously deposited first deposition material 2 as well as over the other portions of the substrate 6. The blanket deposition occurs by electroplating from an anode (not shown), composed of the second material, through an appropriate plating solution (not shown), and to the cathode/substrate 6. The entire two-material layer is then planarized to achieve precise thickness and flatness as shown in FIG. 2D. After repetition of this process for all layers, the multi-layer structure 20 formed of the second material 4 (i.e. structural material) is embedded in first material 2 (i.e. sacrificial material) as shown in FIG. 2E. The embedded structure is etched to yield the desired device, i.e. structure 20, as shown in FIG. 2F.

Various components of an exemplary manual electrochemical fabrication system 32 are shown in FIGS. 3A-3C. The system 32 consists of several subsystems 34, 36, 38, and 40. The substrate holding subsystem 34 is depicted in the upper portions of each of FIGS. 3A-3C and includes several components: (1) a carrier 48, (2) a metal substrate 6 onto which the layers are deposited, and (3) a linear slide 42 capable of moving the substrate 6 up and down relative to the carrier 48 in response to drive force from actuator 44. Subsystem 34 also includes an indicator 46 for measuring differences in vertical position of the substrate which may be used in setting or determining layer thicknesses and/or deposition thicknesses. The subsystem 34 further includes feet 68 for carrier 48 which can be precisely mounted on subsystem 36.

The CC mask subsystem 36 shown in the lower portion of FIG. 3A includes several components: (1) a CC mask 8 that is actually made up of a number of CC masks (i.e. submasks) that share a common support/anode 12, (2) precision X-stage 54, (3) precision Y-stage 56, (4) frame 72 on which the feet 68 of subsystem 34 can mount, and (5) a tank 58 for containing the electrolyte 16. Subsystems 34 and 36 also include appropriate electrical connections (not shown) for connecting to an appropriate power source (not shown) for driving the CC masking process.

The blanket deposition subsystem 38 is shown in the lower portion of FIG. 3B and includes several components: (1) an anode 62, (2) an electrolyte tank 64 for holding plating solution 66, and (3) frame 74 on which feet 68 of subsystem 34 may sit. Subsystem 38 also includes appropriate electrical connections (not shown) for connecting the anode to an appropriate power supply (not shown) for driving the blanket deposition process.

The planarization subsystem 40 is shown in the lower portion of FIG. 3C and includes a lapping plate 52 and associated motion and control systems (not shown) for planarizing the depositions. Additional features are described in U.S. Pat. No. 6,029,630, incorporated herein by reference.

A need exists in various fields for miniature devices having improved characteristics, reduced fabrication times, reduced fabrication costs, simplified fabrication processes, greater versatility in device design, improved selection of materials, improved material properties, more cost effective and less risky production of such devices, and/or more independence between geometric configuration and the selected fabrication process.

In particular, when making micro-scale or millimeter scale parts handling of the parts may be difficult or burdensome. During the batch fabrication of many hundreds, thousands, or even tens of thousands of parts simultaneously, in situ inspections or testing may provide knowledge that one or more of the parts have defects or are likely to have defects. Improved methods are needed for distinguishing or separating failed parts from good parts.

### SUMMARY OF THE INVENTION

In a first aspect of the invention a method for batch fabrication of a plurality of multi-layer three-dimensional parts, includes: (a) forming a first layer on a substrate, including: (i) depositing at least one sacrificial material for the first layer and depositing at least one structural material for the first layer such that the deposited sacrificial material for the first layer and the deposited structural material for the first layer occupy different lateral portions of the first layer; and thereafter; (ii) planarizing the deposited sacrificial material for the first layer and the deposited structural material for the first layer to have a common height to set a boundary level for the first layer; (b) forming at least one additional layer adjacent to and adhered to a preceding layer, wherein the forming of each additional layer includes: (i) depositing at least one sacrificial material for the additional layer and depositing at least one structural material for the additional layer such that the deposited sacrificial material for the additional layer and the deposited structural material for the additional layer occupy different lateral portions of the additional layer; and thereafter; (ii) planarizing the at least one deposited sacrificial material for the additional layer and the at least one deposited structural material for the additional layer to have a common height to set a boundary level for the additional layer; and (c) after forming the first layer and the at least one additional layer, etching deposited sacrificial material from each of the first layer and the at least one additional layer to reveal the plurality of three-dimensional parts, (d) during formation of the first layer or the at least one additional layer or after formation of the at least one additional layer, directly or indirectly identifying failed parts as specific parts or parts within specific regions where at least one fabrication criterion has failed to be met; and (e) after the identifying of step (d), but before the etching of step (c) modifying each failed part via a modification step.

The modification step may be (1) using a computer controlled laser and scanning system to cut each failed part into at least two pieces where no piece of the cut part is greater than 90% of a good part; (2) using a computer controlled laser and scanning system to remove at least 10% of each failed part; (3) using a computer controlled laser and scanning system to remove an assembly feature from each failed part such that the failed parts are incapable of being assembled with at least one other component that a good part would be put to use with; (4) using a computer controlled laser and scanning system to remove an identification feature from each failed part such that each failed part is incapable of being identified as a good part; (5) using a computer controlled machining system to direct at least one physical cutting element onto the failed parts to cut each failed part into at least two pieces where no piece of the cut part is greater than 90% of a good part; (6) using a computer controlled machining system to direct at least one physical cutting element to remove at least 10% of each failed part; (7) using a computer controlled machining system to direct at least one physical cutting element system to remove an assembly feature from each failed part such that the failed parts are incapable of being assembled with at least one other component that a good part would be put to use with; and (8) using a computer controlled machining system to direct at least one physical cutting element system to remove an identification feature from each failed part such that each failed part is incapable of being identified as a good part.

Numerous variations of the first aspect of the invention are possible and include for example:

(A) after formation of the first layer and the at least one additional layer but prior to the modifying of step (e), coating a last layer of the at least one additional layer with a removable shielding material and removing the shielding material prior to or during the etching of step (c); (B) the three-dimensional parts comprise a part selected from the group consisting of (1) compliant probe structures for use in testing electronic components, (2) probe structures consisting of a compliant probe body and a contact tip material different from a material of the probe body, and (3) probe structures having a compliant probe body including a core material and a shell material which are different; (C) the modifying step is performed at a time selected from the group consisting of: (1) only after all layers of the at least one additional layer have been formed; (2) in a plurality of steps with at least one of the steps occurring prior to the forming of the last layer of the at least one additional layer

In a second aspect of the invention a method for batch fabrication of a plurality of multi-layer three-dimensional parts, includes: (a) forming a plurality of layers, with the first being formed on a substrate and at least one subsequent layers being formed on a previously formed layer wherein the formation of each of a plurality of given layers includes: (i) depositing at least one sacrificial material for the given layer and depositing at least one structural material for the given layer such that the deposited sacrificial material and the deposited structural material occupy different lateral portions of the given layer; and thereafter (ii) planarizing the deposited sacrificial material and the deposited structural material to have a common height to set a boundary level for the given layer; (b) after forming the plurality of layers, removing deposited sacrificial material from each of the first layer and the at least one subsequent layer to reveal the plurality of three-dimensional parts, (c) wherein the process additionally includes: (i) identifying specific parts or parts within specific regions where at least one fabrication criterion has failed to be met; (ii) associating identified parts with specific locations where part modifications will be made; (iii) after the associating but before completion of removal of sacrificial material, performing a specific part modification step selected from the group consisting of: (1) using a computer controlled laser and scanning system to dissect the specific parts; (2) using a computer controlled laser and scanning system to remove the specific parts; (3) using a computer controlled laser and scanning system to remove a critical and apparent feature from the specific parts; (4) using a computer controlled machining system to direct at least one physical cutting element onto the specific parts to dissect the specific parts; (5) using a computer controlled machining system to direct at least one physical cutting element onto the specific parts to remove the specific parts; (6) using a computer controlled machining system to direct at least one physical cutting element onto the specific parts to remove a critical and apparent feature from the specific parts.

In a third aspect of the invention a method for batch fabrication of a plurality of multi-layer three-dimensional parts, includes: (a) forming a plurality of layers with each successive layer formed on a previously formed layer with each including at least one sacrificial material and at least one structural material from which the plurality of parts are formed; (b) identifying specific parts or parts within specific regions where at least one fabrication criteria failed during the forming; (c) associating identified parts with specific locations where part modifications will be made; (d) after the associating, performing a specific part modification step selected from the group consisting of: (1) using a computer controlled laser and scanning system to dissect the specific parts; (2) using a computer controlled laser and scanning system to remove the specific parts; (3) using a computer controlled laser and scanning system to remove a critical and apparent feature from the specific parts; (4) using a computer controlled machining system to direct at least one physical cutting element onto the specific parts to dissect the specific parts; (5) using a computer controlled machining system to direct at least one physical cutting element onto the specific parts to remove the specific parts; (6) using a computer controlled machining system to direct at least one physical cutting element onto the specific parts to remove a critical and apparent feature from the specific parts; and (e) after forming the plurality of layers, removing sacrificial material from each of the plurality of layers to reveal the plurality of three-dimensional parts.

### BRIEF DESCRIPTION OF THE DRAWINGS

FIGS. 1A-1C schematically depict side views of various stages of a CC mask plating process, while FIGS. 1D-1G schematically depict side views of various stages of a CC mask plating process using a different type of CC mask.

FIGS. 2A-2F schematically depict side views of various stages of an electrochemical fabrication process as applied to the formation of a particular structure where a sacrificial material is selectively deposited while a structural material is blanket deposited.

FIGS. 3A-3C schematically depict side views of various example subassemblies that may be used in manually implementing the electrochemical fabrication method depicted in FIGS. 2A-2F.

FIGS. 4A-4F schematically depict the formation of a first layer of a structure using adhered mask plating where the blanket deposition of a second material overlays both the openings between deposition locations of a first material and the first material itself.

FIG. 4G depicts the completion of formation of the first layer resulting from planarizing the deposited materials to a desired level.

FIGS. 4H and 4I respectively depict the state of the process after formation of the multiple layers of the structure and after release of the structure from the sacrificial material.

FIG. 5 provides a block diagram of a sample design-to-use process that may incorporate a method of one of the first through sixth embodiments of the present invention or one of their variations.

FIG. 6 provides a flowchart of the layer formation process and the failed or defective part handling process of a first embodiment of the invention.

FIGS. 7A and 7B provide a side cut view (FIG. 7A) and a top view (FIG. 7B) of the last layer respectively, of parts formed from a batch, multilayer, multi-material fabrication process.

FIGS. 7C and 7D provide perspective views of the batch fabricated parts of FIGS. 7A and 7B wherein the parts are shown prior to release in FIG. 7C and after release in FIG. 7D.

FIGS. 7E and 7F provide perspective views similar to those of FIGS. 7C and 7D with the exception that the first and fourth parts from the left are shown as being cut through (i.e. destroyed or dissected into two pieces) due to anticipated failures during the fabrication process.

FIG. 8 provides a flowchart of a second embodiment of the invention which is similar to that of FIG. 6 with the exception that protective coating is formed over the last structural material layer to protect the good parts from material that will be removed from the failed parts during the cutting or destruction step(s).

FIGS. 9A and 9B provide images of a multi-layer, multi-material build similar to FIGS. 7A and 7E, respectively, but where a covering layer (e.g. of sacrificial material or photoresist) is applied and then the cutting of failed parts occurs (as can be seen from the resulting openings shown in FIG. 9B) so that debris is not deposited onto the structural material of the good parts.

FIG. 10 provides a flowchart of a third embodiment of the invention where cutting of failed parts occurs during the formation of least some layers prior to completion of the layer-by-layer build up.

FIG. 11A provides a perspective view similar to that of FIG. 7E showing that the first and fourth parts from the left have been cut.

FIGS. 11B-11F show cut views from the perspective of the arrows of line 11G-11G of FIG. 11A for various states of the process during formation of a sample layer (i.e. the 1st layer as illustrated) and in particular of a portion of part that will be dissected according to the embodiment of FIG. 10.

FIG. 11G provides a perspective view of the dissected example 3-layer part from the perspective of overlaid line 11G-11G of FIG. 11A after release from the substrate and sacrificial material.

FIG. 11H provides a perspective view of the whole, or good, example 3-layer part from the perspective of overlaid line 11H-11H of FIG. 11A after release from the substrate and sacrificial material.

### DETAILED DESCRIPTION OF PREFERRED EMBODIMENTS

Electrochemical Fabrication in General

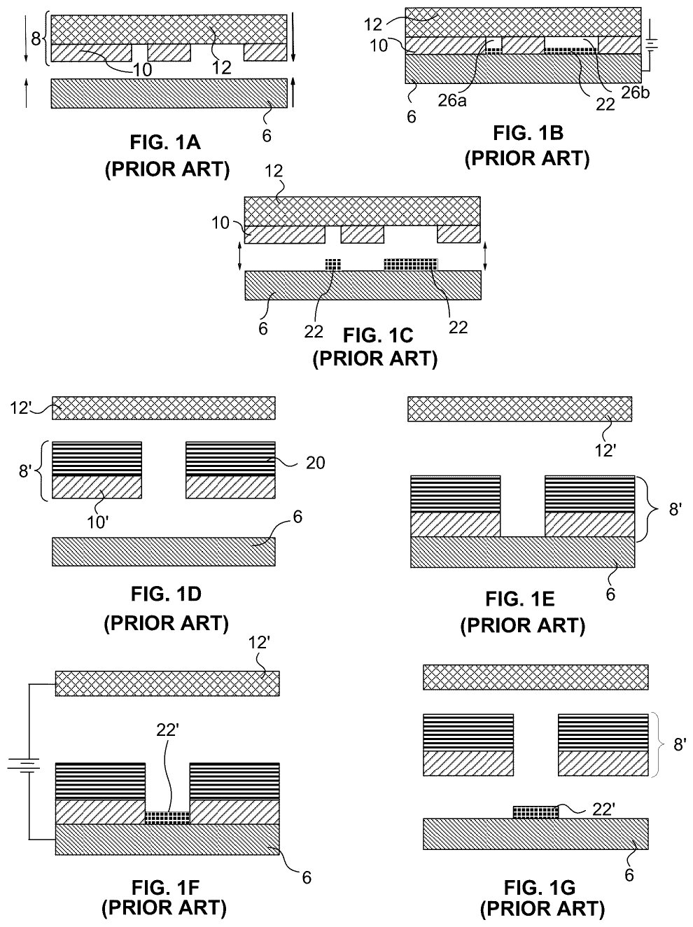

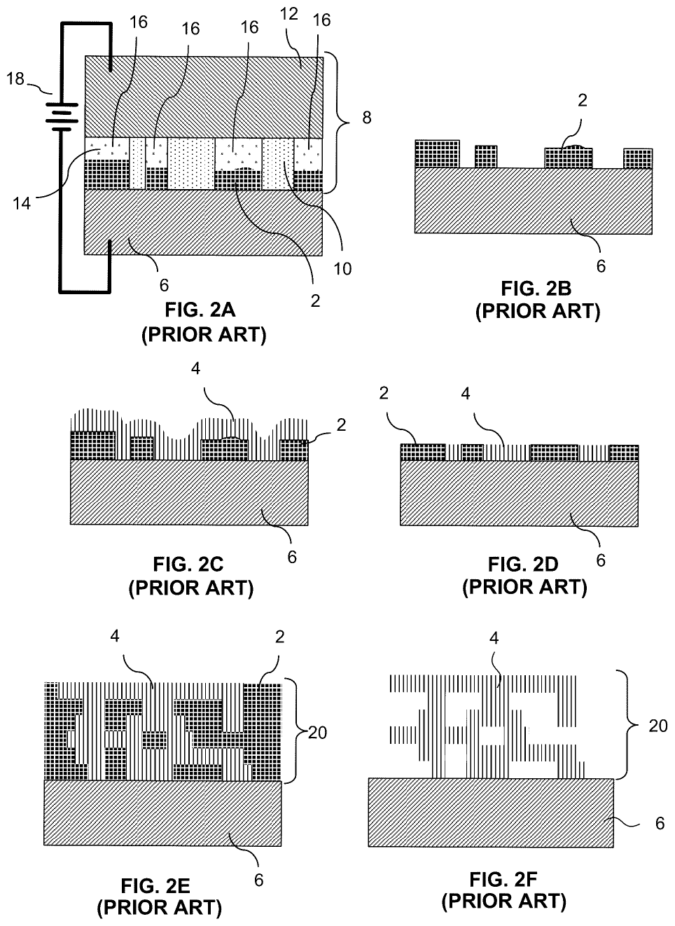

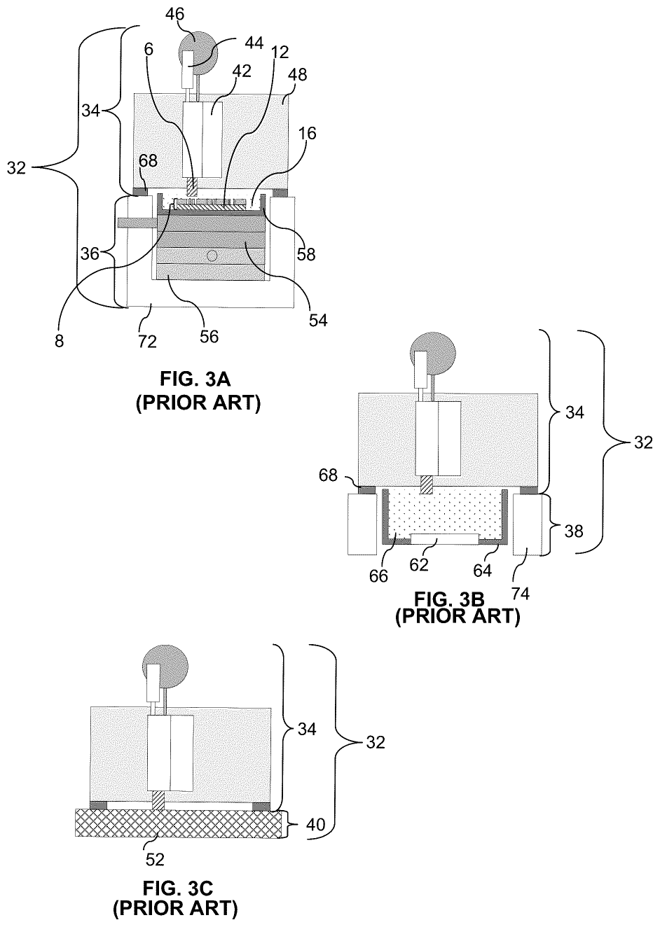

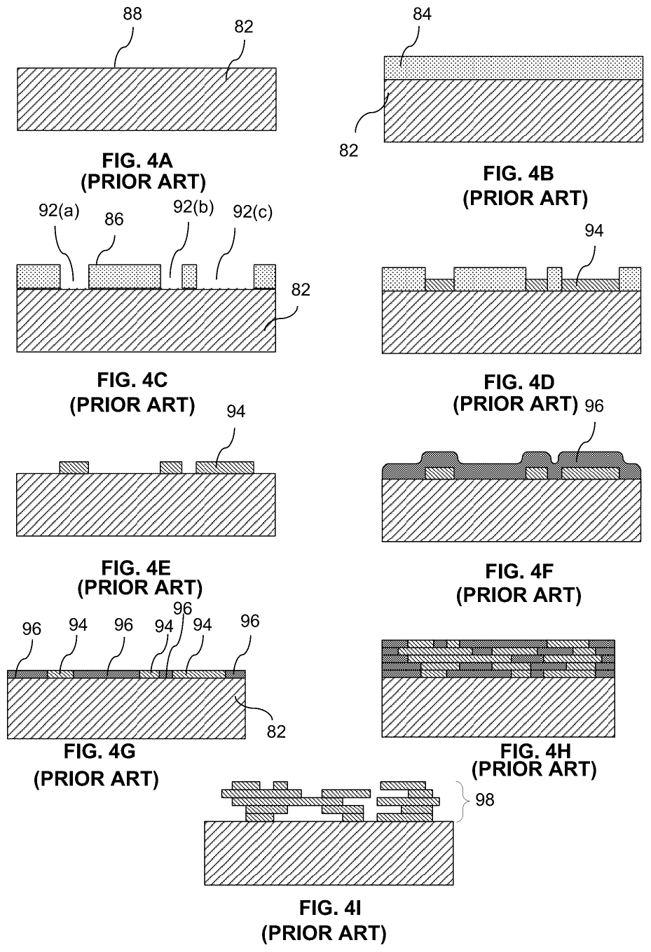

FIGS. 1A-1G, 2A-2F, and 3A-3C illustrate various features of one form of electrochemical fabrication. FIGS. 4A-4I illustrate side views of various states in an alternative multi-layer, multi-material electrochemical fabrication process. FIGS. 4A-4G illustrate various stages in the formation of a single layer of a multi-layer fabrication process where a second metal is deposited on a first metal as well as in openings in the first metal so that the first and second metal form part of the layer. In FIG. 4A a side view of a substrate 82 having a surface 88 is shown, onto which patternable photoresist 84 is cast as shown in FIG. 4B. In FIG. 4C, a pattern of resist is shown that results from the curing, exposing, and developing of the resist. The patterning of the photoresist 84 results in openings or apertures 92(a)-92(c) extending from a surface 86 of the photoresist through the thickness of the photoresist to surface 88 of the substrate 82. In FIG. 4D a metal 94 (e.g. nickel) is shown as having been electroplated into the openings 92(a)-92(c). In FIG. 4E the photoresist has been removed (i.e. chemically stripped) from the substrate to expose regions of the substrate 82 which are not covered with the first metal 94.

In FIG. 4F a second metal 96 (e.g. silver) is shown as having been blanket electroplated over the entire exposed portions of the substrate 82 (which is conductive) and over the first metal 94 (which is also conductive). FIG. 4G depicts the completed first layer of the structure which has resulted from the planarization of the first and second metals down to a height that exposes the first metal and sets a thickness for the first layer. In FIG. 4H the result of repeating the process steps shown in FIGS. 4B-4G several times to form a multi-layer structure is shown where each layer consists of two materials. For most applications, one of these materials is removed as shown in FIG. 4I to yield a desired 3-D structure 98 (e.g. component or device). Various embodiments of various aspects of the invention are directed to formation of three-dimensional structures from materials some, or all, of which may be electrodeposited (as illustrated in FIGS. 1A-4I) or electroless deposited. Some of these structures may be formed from a single build level formed from one or more deposited materials while others are formed from a plurality of build layers each including at least two materials (e.g. two or more layers, more preferably five or more layers, and most preferably ten or more layers).

### Definitions

“Structural material” as used herein refers to a material that remains part of the structure when put into use.

“Primary structural material” as used herein is a structural material that forms part of a given build layer and which is typically deposited or applied during the formation of that build layer and which makes up more than 20% of the structural material volume of the given build layer

“Secondary structural material” as used herein is a structural material that forms part of a given build layer and is typically deposited or applied during the formation of the given build layer but is not a primary structural material as it individually accounts for only a small volume of the structural material associated with the given layer. A secondary structural material will account for less than 20% of the volume of the structural material associated with the given layer.

“Sacrificial material” is material that forms part of a build layer but is not a structural material. Sacrificial material on a given build layer is separated from structural material on that build layer after formation of that build layer is completed and more generally is removed from a plurality of layers after completion of the formation of the plurality of layers during a “release” process that removes the bulk of the sacrificial material or materials. In general sacrificial material is located on a build layer during the formation of one, two, or more subsequent build layers and is thereafter removed in a manner that does not lead to a planarized surface. Materials that are applied primarily for masking purposes, i.e. to allow subsequent selective deposition or etching of a material, e.g. photoresist that is used in forming a build layer but does not form part of the build layer) or that exist as part of a build for less than one or two complete build layer formation cycles are not considered sacrificial materials as the term is used herein but instead shall be referred as masking materials or as temporary materials. These separation processes are sometimes referred to as a release process and may or may not involve the separation of structural material from a build substrate.

“Primary sacrificial material” as used herein is a sacrificial material that is located on a given build layer and which is typically deposited or applied during the formation of that build layer and which makes up more than 20% of the sacrificial material volume of the given build layer. In some embodiments, the primary sacrificial material may be the same on each of a plurality of build layers or may be different on different build layers. In some embodiments, a given primary sacrificial material may be formed from two or more materials by the alloying or diffusion of two or more materials to form a single material.

“Secondary sacrificial material” as used herein is a sacrificial material that is located on a given build layer and is typically deposited or applied during the formation of the build layer but is not a primary sacrificial material as it individually accounts for only a small volume of the sacrificial material associated with the given layer. A secondary sacrificial material will account for less than 20% of the volume of the sacrificial material associated with the given layer.

In batch fabrication of structures or parts wherein good and bad parts are distinguished with the bad parts being cut up or destroyed so that only parts that are believed to be “good” remain whole. In a first embodiment, destruction occurs after all layers are formed. In a second embodiment, the final layer of the build is provided with a protective coating such that upon destruction, debris, from destroyed parts, does not become deposited on good parts. In a third embodiment, destruction of failed parts occurs during layer build up and possibly at the end of layer build up. In some embodiments, destroyed parts may be separated from good parts prior to supplying the good parts to a customer while in other embodiments some or all of the destroyed parts may be shipped with the good parts with the knowledge that the destroyed parts cannot be inadvertently used in place of good parts.

Each embodiment of the invention includes the fabrication of a plurality of parts or structures from a plurality of multi-material layers with each layer including at least one structural material and at least one sacrificial material. In the most preferred embodiments, though not necessarily all embodiments, each layer is planarized to set an upper boundary level for the layer while a planarization of the materials associated with the prior layer sets the lower boundary level for a current layer. In the most preferred embodiments, each successive layer is adhered to a previously formed layer during its formation. In some embodiment variations, layer formation is by one of the processes set forth herein above (e.g. selective deposition of a first material, blanket deposition of a second material, and thereafter the two materials are planarized). In some embodiment variations one or more part layers may be formed from three or more materials (e.g. two structural materials and one sacrificial material or three or more structural materials and one or more sacrificial materials). In still other embodiments, layer formation may vary from layer to layer, while in still other embodiments, some or all layer formation may be by other methods (e.g. laying down sheets of material, cutting the sheets into desired cross-sectional patterns and bonding the sheets together either before or after cutting, etc.). In the most preferred embodiments, inspections or tests are performed after selected process steps during the formation of layers (e.g. once per layer or multiple times per layer). When problems are found, individual parts or regions are flagged as “bad” or “failed”. If too many problems occur on a single layer or if too many problems have accumulated from the formation of a plurality of layers, a decision may be made to erase one or more layers and reform them to improve overall yield. However, if failures have not met a “reform” threshold, failed regions are simply flagged and building is allowed to continue.

In the embodiments, at some point in the process, data associated with flagged parts or regions is converted into data associated with destruction paths (e.g. cutting paths) that will be used in destroying the “bad” parts. After formation of one or more layers, and in the most preferred embodiments after formation of all layers, destruction path data is used to direct a destruction tool onto the surface of the last formed layer with a desired depth of destruction such that bad parts are unambiguously distinguished from good parts. In different embodiments, the destruction tools may take on any of a number of effective forms. For example, in some embodiments, a pulsed or CW laser beam of appropriate power, diameter, wavelength, pulse width, and the like may be directed onto appropriate locations on the surface of a last formed layer to provide ablative cutting of bad parts (e.g. using a YVO4 laser or a diode pumped doubled YAG laser (e.g. at 532 nm) or some other frequency multiplied solid state laser). In such embodiments, the laser beam may be moved over the surface while in others the surface may be moved under a fixed beam position. In such embodiments multiple passes of the beam may be used to achieve a desired cutting depth (e.g. two passes to a thousand passes or more). In other embodiments the destruction tool may take a physical form such as for example that of an appropriately operated punch, a mill bit, or a drill. In the most preferred embodiments, the size of the parts is small, e.g. less than 1 mm in height and less than several centimeters on an edge. In some embodiments the height of a part in the layer stacking direction may be less than 200 or even 100 um while the lateral dimensions may be on the order of 10 um to 10 mm. In such embodiments a cutting tool width may be appropriately sized for the circumstances. For example for the part sizes noted above the tool width may be on the order of a few microns to a few tens of microns while positioning accuracy of the tool or of the part relative to the tool may be on the order to microns to tens of microns.

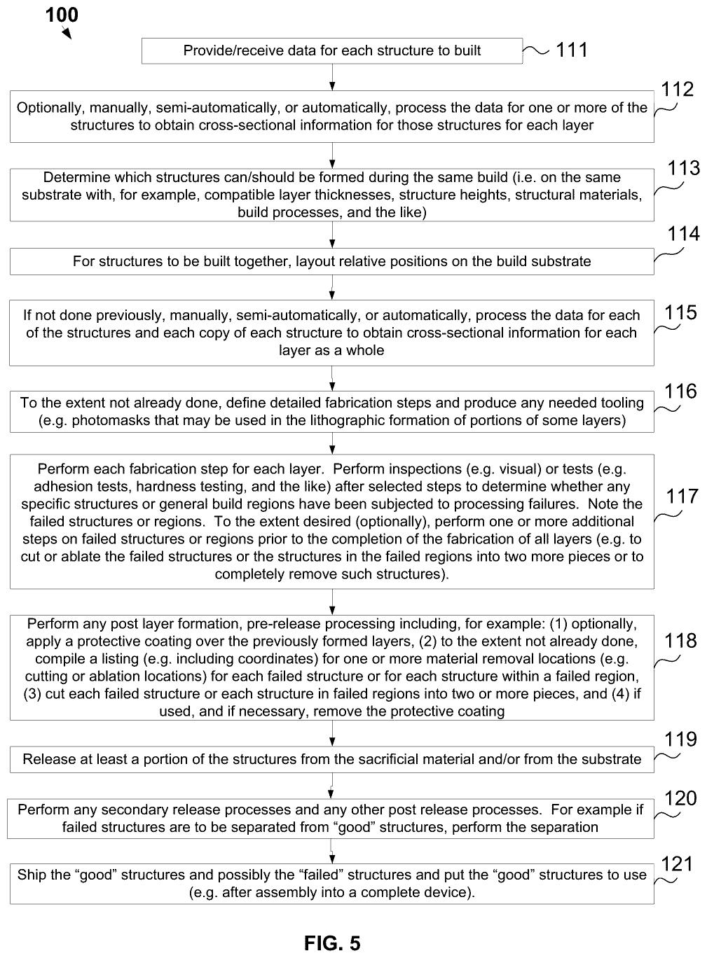

FIG. 5 provides a block diagram of a sample design-to-use process 100 that may incorporate a method of one of the first three embodiments of the present invention. The process starts with element 111 which calls for the providing of, or receipt of, data for each part to be built. Element 112 follows element 111 and optionally calls for the manual, semi-automatic, or automatic processing of the data for one or more of the parts to obtain cross-sectional information for those parts for each layer to be built. Element 113 follows element 112 and calls for determination of which parts can and will be formed during the same build (i.e. on the same substrate with, for example, compatible layer thicknesses, part heights, structural materials, build processes, and the like. Element 114 follows element 113 and calls for the laying out of parts to their desired build locations and orientations. This processing of elements 111-115 may be performed with the aid of a programmed computer executing the program in conjunction with appropriate input data. Element 115 follows element 114, and to the extent not previously done (e.g. in element 112), calls for the manual, semi-automatic, or automatic processing of the data for each part and copy to be formed to obtain cross-sectional information for those parts for each layer to be built. Element 116 follows element 115, and to the extent not already done, calls for the defining of detailed fabrication steps and the producing of needed tooling, such as, for example, photomasks that may be used in the lithographic formation of portions of some layers).

Element 117 follows element 116 and calls for the performing of each fabrication step for production of each layer. The defining, performing, and/or controlling of operational steps, parameters and associated equipment for elements 116 and 117 may involve the use of a programmed computer in conjunction with manual or automated processing and inspection equipment. Element 117 also calls for the performing of inspections (e.g. visual) or tests (e.g. adhesion tests, hardness tests, composition tests, and the like) after selected steps to determine whether any specific parts or general build regions have been subjected to processing failures. It also calls for noting or recording the failed parts or regions (e.g. locations on a wafer where failures exist or are likely to exist). Finally to the extent desired, it optionally calls for the performing of one or more additional steps on the failed parts or regions prior to the completion of the fabrication of all layers. These additional steps may include for example the cutting or ablation of failed parts into two or more pieces or the complete removal of the failed parts.

Element 118 follows element 117 and calls for the performing of any post layer formation, pre-release processing including, for example: (1) optionally, applying a protective coating over the previously formed layers, (2) to the extent not already done, compiling a listing (e.g. including coordinates) for one or more removal locations or removal patterns for each failed part or for each part within a failed region, (3) cutting or ablating each failed part or each part in failed regions into two or more pieces or completely removing such parts, (4) if used and if necessary removing the protective coating. This processing of element 118 may be performed with the aid of a programmed computer in conjunction with manual or automated processing equipment.

Element 119 follows element 118 and calls for the release of at least a portion of the parts from the sacrificial material and/or from the substrate. Element 120 follows element 119 and calls for performing any secondary release processes and any other post release processes. For example, a post release process of element 120 may involve the physical separating or sorting of “good” parts from “bad” parts. Finally element 121 follows element 120 and calls for the shipping of the “good” parts and possibly the “failed” parts to a customer or the putting of the “good” parts to use (e.g. after assembly into a complete device). Any required separating or sorting may involve the use of manual or computer controlled automatic processing tools or equipment.

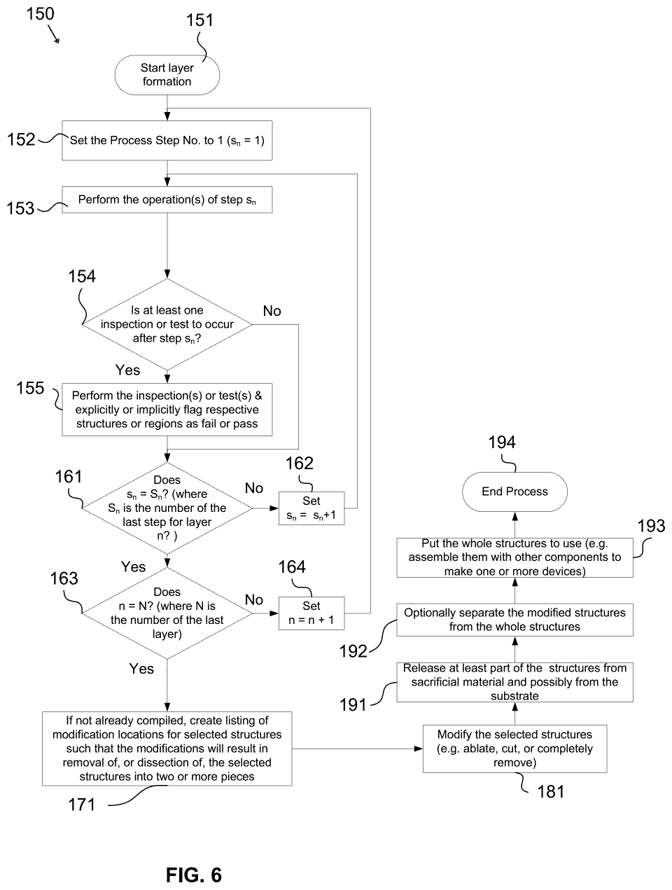

FIG. 6 provides a flowchart of the layer formation and the failed or defective part handling process 150 according to a first embodiment of the invention. Element 151 calls for the starting of the process. Element 152 follows element 151 and calls for the setting of a process Step No., sn, equal to one. For each layer this process step number is associated with a specific process operation or set of operations that are to be performed to fabricate the layer of the parts. These process numbers and associated operations or steps may be fixedly defined in advance or may be variably defined and modified depending on the results of prior process steps, inspection steps or tests. Element 153 follows element 152 and calls for the performance of the operation(s) of step sn. Step 154 questions whether or not an inspection step will follow the operation(s) of step sn. If the answer is “yes”, the process moves to element 155. Otherwise it moves to element 161.

Element 155 calls for the performance of the inspection(s) or test(s) and explicitly or implicitly results in the flagging of respective parts or regions as “failed” or “passed”. Element 161 makes an inquiry as to whether the just performed step sn is equal to the last step number Sn for the layer “n”. If “no” the process increments sn by one (element 162) and loops back to element 153. If “yes” the process moves forward to element 163 where an inquiry is made as to whether or not the current layer number “n” is equal to the last layer number “N”. If “no” the process increment n to n+1 (element 164) and loops back to element 152 in preparation for forming a next layer. If “yes” the process moves forward to element 171.

Element 171, if not already compiled, calls for the creation of a listing of modification locations for selected parts such that the modifications will result in the removal of the selected parts or the dissection of the selected parts into two or more pieces. This may involve a translation of identified specific failed parts to specific locations on those failed parts where the specific locations define the regions to actually be modified. In some embodiment variations, it may be necessary to designate complete modification paths (e.g. scanning paths for laser beams or cutting paths for mechanical elements). Element 181 follows element 171 and calls of the modification of the selected parts (e.g. ablation, cutting, or complete removal).

Element 191 follows element 181 and calls for the release of at least part of the parts from the sacrificial material and possibly from the substrate. Element 192 follows element 191 and calls for the optional separation of the modified parts (i.e. bad parts) from the whole parts (i.e. good parts). Element 193 follows element 192 and calls for the putting of the whole parts to use such as assembling them with other components to make one or more devices. The process ends with element 194 following element 193.

The process 150 of FIG. 6 provides generalized steps for the fabrication of parts and the distinguishing of good parts from bad parts and the putting to use of the good parts. It is clear that many variations of the process are possible. Some variations might add additional steps, some variations might change the order of performing some steps, and some variations may remove some steps. Examples of process variations are set forth hereinafter.

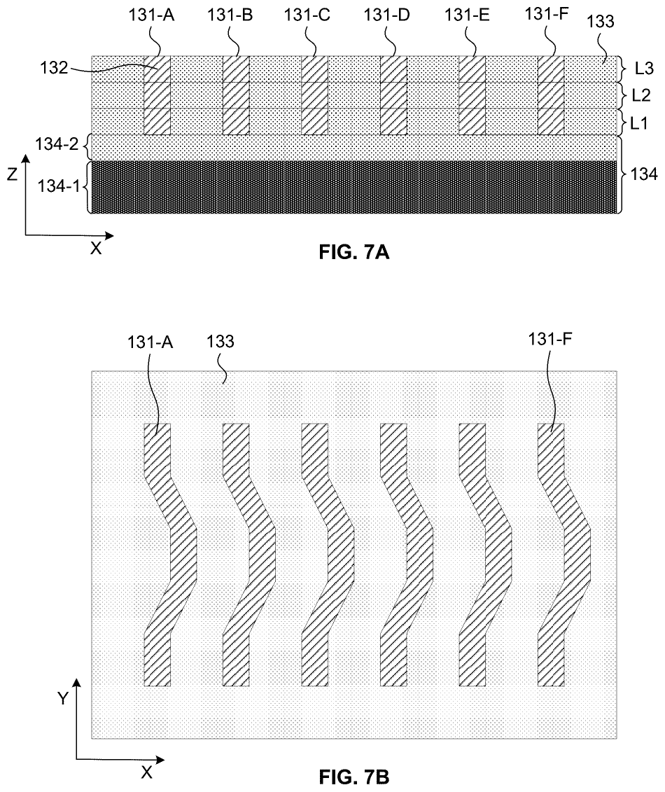

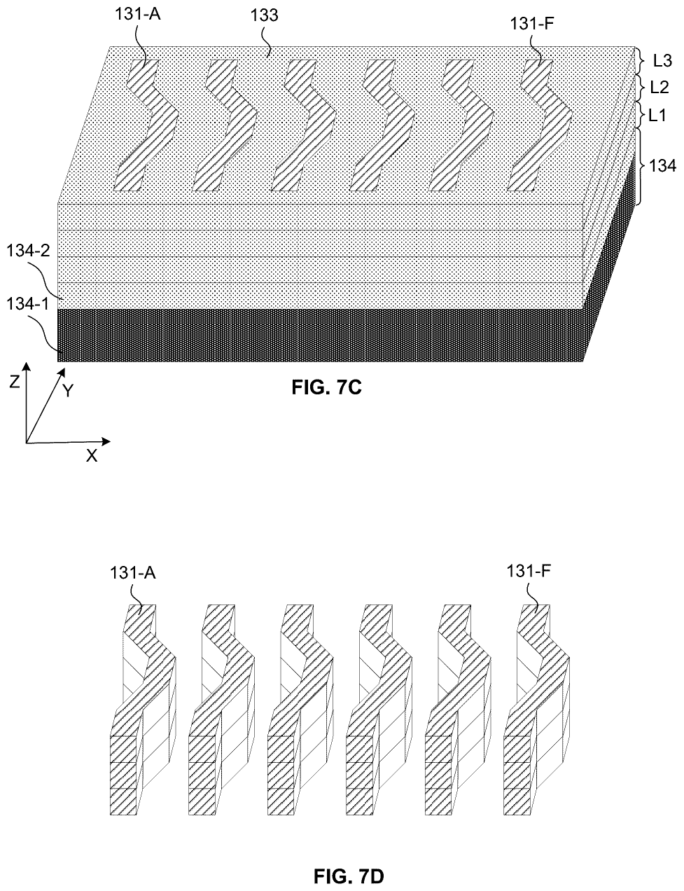

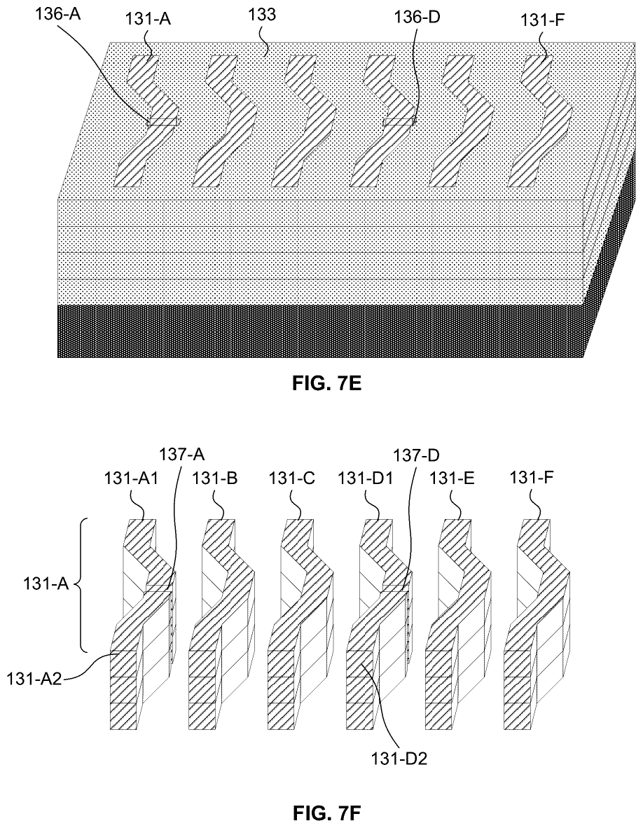

FIG. 7A provides a side cut view of a plurality of example parts 131-A to 131-F formed from a structural material 132 on three layers L1, L2 and L3. In addition to the structural material L1-L3 were also formed with a sacrificial material 133. Layer 1 (L1) of the parts is formed on a release layer 134-2 that was formed on a substrate material 134-1 wherein together 134-1 and 134-2 may be considered a complete substrate 134. FIG. 7B provides a top view of the formed parts 136-A to 136-F wherein lateral regions (or X and Y regions) of individual parts can be seen. The substrate 134 (i.e. 134-1) may be considered to be reusable for building other parts after reformation of a release layer 134-2 that may be removed or become damaged during the fabrication of a previous set of parts or during the release of those parts from the substrate.

FIGS. 7C and 7D provide perspective views of the batch fabricated parts of FIGS. 7A and 7B. In FIG. 7C the parts are shown in the same process state as that of FIGS. 7A and 7B (i.e. prior to release of the parts from the sacrificial material 133 and from the substrate 134-1). FIG. 7D shows the six three layer parts 131-A to 131-F after release under the assumption that all six parts were either successfully formed or at least were not subject to the disambiguation of good parts and bad parts of the first embodiment of the invention.

FIGS. 7E and 7F provide perspective views similar to those of FIGS. 7C and 7D with the exception that the first and fourth parts from the left are shown as being modified (i.e. in this example destroyed or dissected into two pieces) due to failures or anticipated failures associated with the process of forming these two particular parts. FIG. 7E shows the state of the process after part modification is performed to cut through or dissect parts 131-A and 131-D leaving voids 136-A and 136-D respectively through each of part layers L1 to L3. FIG. 7F shows the state of the process after release of the structures 131-A to 131-F where 131-A and 131-D are each shown in two pieces 131-A1 and 131-A2 and 131-D1 and 131-D2, respectively, with removed sections 137-A and 137-D, respectively. As the part fragments 131-A1, 131-A2, 131-D1, and 131-D2 are about half the size of the whole parts 131-B, 131-C, 131-E, and 131-F there is little or no likelihood of the bad parts being inadvertently put to use instead of the good parts.

FIGS. 7A-7F are intended to make clear some of the features of the embodiment of FIG. 6. It will be understood by those of skill in the art that the process of FIG. 6 and FIGS. 7A-7F may be used to produce a wide variety of simple, complex and multi-component parts and assemblies. Some parts may be, for example, probes for electrical test applications of the vertical type or cantilever type wherein the probes could be formed on their sides or standing vertically. Some parts may be single or multi-component medical device parts while others may be RF devices, switches, sensors (e.g. pressure sensors, inertial measurement sensors), scanning mirrors, electrostatic actuators, heatuators, escapement mechanisms for timing applications, camera components, ink jet print head components, hard disk drive components, and the like. In some variations, parts may be formed from more than one structural material and even more than one structural material on a single layer (e.g. to form contact or high abrasion regions, e.g. probe tips, from a distinct material and/or to apply a bonding aid to structural regions that will undergo bonding, e.g. probe base regions). Parts may be formed from fewer layers (e.g. 1 or 2) or formed from more layers (e.g. 20 or more layers). Parts may be formed of metals only, non-metals (e.g. semiconductors, dielectrics, ceramics plastics, composites, or the like), or combinations of metals and non-metals. Some parts may deviate from strict layer-by-layer formation methods while still being formed from a plurality of multi-material planar layers (e.g. to allow interlacing) such as by the methods taught in U.S. Pat. No. 7,252,861, referenced elsewhere herein. Some embodiments may not require complete dissection of parts into multiple components but simply require sufficient modification to ensure that disambiguation of good and bad parts is provided. In some embodiments, selective deposition of materials may give way to blanket deposition, selective etching or ablation, followed by further blanket deposition into the voids that were created. In some embodiments, some portion of a sacrificial material may be encapsulated in a shell of surrounding structural material such that cored parts are formed due to the inability of the sacrificial material to be removed. In some embodiment variations, parts may be modified by dissecting the part into more than two pieces (e.g. 3, 4 or more pieces). In other variations, failed part modification may include the complete ablation, milling, or otherwise cutting away of the entire failed part possibly along with some of the neighboring sacrificial material.

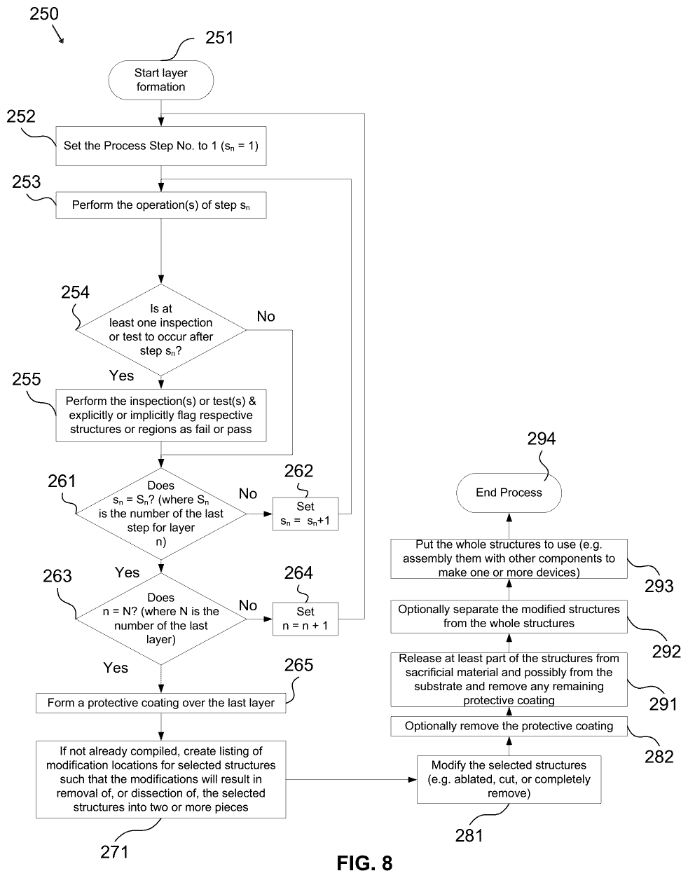

FIG. 8 provides a flowchart of a second process embodiment 250 of the invention which is similar to that of FIG. 6 with the exception that protective coating is formed over the last structural material layer to protect the good parts from material that will be removed from the failed parts during the modification step or steps, e.g. ablation, cutting, punching, drilling, or milling.

Element 251 calls for the starting of the process. Element 252 follows element 251 and calls for the setting of a process Step No., sn, equal to one. For each layer this process step number is associated with a specific process operation or set of operations that are to be performed to fabricate the layer of the parts. These process numbers and associated operations or steps may be fixedly defined in advance or may be variably defined and modified depending on the results of prior process steps, inspection steps or tests. Element 253 follows element 252 and calls for the performance of the operation(s) of step sn. Element 254 questions whether or not an inspection step will follow the operation(s) of step sn. If the answer is “yes”, the process moves to element 255. Otherwise it moves to element 261.

Element 255 calls for the performance of the inspection(s) or test(s) and explicitly or implicitly results in the flagging of respective parts or regions as “failed” (i.e. bad) or “passed” (i.e. good). Element 261 makes an inquiry as to whether the just performed step sn is equal to the last step number Sn for the layer “n”. If “no” the process increments sn by one (element 262) and loops back to element 253. If “yes” the process moves forward to element 263 where an inquiry is made as to whether or not the current layer number “n” is equal to the last layer number “N”. If “no” the process sets n=n+1 (element 264) and loops back to element 252 in preparation for forming a next layer. If “yes” the process moves forward to element 265 which calls for the formation of a protective coating over the last formed layer so that upon modification of selected structures removed structural material will not be deposited onto the good parts. In different embodiment variations, protective coatings may be formed in different ways and be formed of different materials. For example, the coating may be the same material as the sacrificial material (e.g. copper) and may be deposited by electroplating or electroless plating. In other variations it may be patterned or unpatterned photoresist.

Element 271 follows element 265 and if not already compiled, calls for the creation of a listing of modification locations for selected parts such that the modifications will result in the removal of the selected parts or the dissection of the selected parts into two or more pieces. Element 281 follows element 271 and calls for modification of the selected parts (e.g. by ablation, cutting, punching, micro-milling, micro-drilling). In some embodiments, failed parts may be completely destroyed or obliterated (e.g. by ablating or machining). Element 282 follows element 281 and calls for the optional removal of the protective coating.

Element 291 follows element 282 and calls for the release of at least part of the parts from the sacrificial material, from any remaining protective coating material, and possibly from the substrate. Element 292 follows element 291 and calls for the optional separation of the modified parts (i.e. bad parts) from the whole parts (i.e. good parts). Element 293 follows element 292 and calls for the putting of the whole parts to use such as assembling them with other components to make one or more devices. The process ends with element 294 following element 293.

The process 250 of FIG. 8 provides generalized steps for the fabrication of parts and the distinguishing of good parts from bad parts and the putting of the good parts to use. It is clear that many variations of the process are possible. Some variations might add additional steps, some variations might change the order of performing some steps, and some variations may remove some steps. Some examples of process variations may be based on the first embodiment or its variations or the embodiments set forth hereafter and their variations.

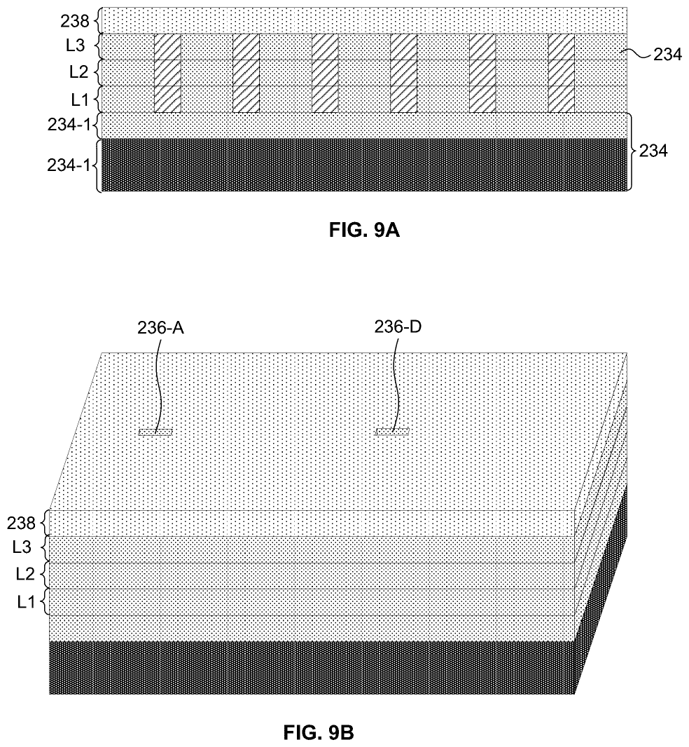

FIGS. 9A and 9B provide images of a multi-layer, multi-material build similar to FIGS. 7A and 7E, respectively, but where a protective coating 238 or covering layer (e.g. of sacrificial material or photoresist) is applied prior to the modification of failed parts (as can be seen from the resulting openings shown in FIG. 9B) so that debris is not deposited onto the structural material of the good parts. After removal of the sacrificial material and the substrate the parts would look like those shown in FIG. 7F with each of the first and fourth parts from the left cut into two pieces. Like elements of FIGS. 9A and 9B are identified with reference numbers similar to those used in FIGS. 7A-7E with the exception that the numbers have been converted from the 100 series to the 200 series.

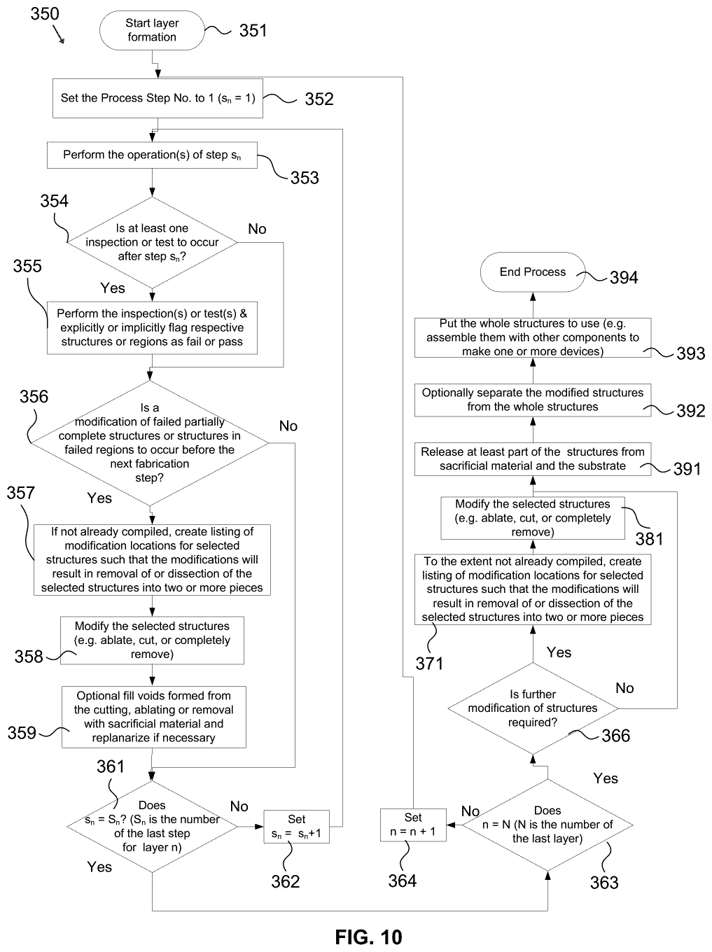

FIG. 10 provides a flowchart of a third process embodiment 350 of the invention where modification (e.g. ablation, cutting, punching, drilling, milling) of failed parts occurs during the formation of least some layers prior to completion of the layer-by-layer build up.

Element 351 calls for the starting of the process. Element 352 follows element 351 and calls for the setting of a process step no. (sn) equal to one. For each layer this process step number is associated with a specific process operation or set of operations that are to be performed to fabricate the layer of the parts. These process numbers and associated operations or steps may be fixedly defined in advance or may be variably defined and modified depending on the results of prior process steps, inspection steps or tests. Element 353 follows element 352 and calls for the performance of the operation(s) of step sn. Step 354 questions whether or not an inspection step will follow the operation(s) of step sn. If the answer is “yes” the process moves to element 355. Otherwise it moves to element 356.

Element 355 calls for the performance of the inspection or test and explicitly or implicitly results in the flagging of respective parts or regions as “failed” or “passed”. Element 356 follows element 354 or element 355 and makes an inquiry as to whether or not modification of failed structures is to occur prior to the next process step. If the answer is “yes” the process moves forward to element 357. Otherwise it moves forward to element 361. Element 357 calls for the compilation, if not already made, of a listing of modification locations for selected structures. Information on depth of modification may also be obtained as the depth of cutting may be different for different parts as some may have undergone previous modification. Element 358 follows element 357 and calls for the modification of the selected structures. Such modification may occur in a number of different ways including for example, by ablation, cutting, punching, drilling, milling, or the like.

Element 359 follows element 358 and calls for the optional filling of any voids formed by element 358. This filling may occur in a blanket or selective manner and may use the same material as the sacrificial material or may be a different material. The filling may even be a dielectric particularly if the removal pattern does not result in electrical isolation of subsequent regions which are to receive electrodeposited material. Filling may be followed by further planarizations. In some variations initial planarizations may always set a level above a desired layer level so that any necessary subsequent planarizations are sure to leave the desired material at the layer boundary level. In such a case, further planarization may occur regardless of whether or not filling occurred.

Element 361 follows element 356 or element 359 and makes an inquiry as to whether the just performed step number sn is equal to the last step number Sn for layer n. If “no”, the process increments sn by one (element 362) and loops back to element 353. If “yes” the process moves forward to element 363 where an inquiry is made as to whether or not the current layer number “n” is equal to the last layer number “N”. If “no” the process increments n to n+1 (element 364) and, the process loops back to element 352 in preparation for forming a next layer. If “yes” the process moves forward to element 366 which makes an inquiry as to whether further modification of the parts is required (e.g. cutting of the last layer of the failed parts). If the answer is “no” the process moves forward to element 381. Otherwise it moves forward to element 371.

Element 371, if not already completed, calls for the creation of a listing of modification locations for selected parts such that the modifications will result in the removal of the selected parts or the dissection of the selected parts into two or more pieces. Element 381 follows element 371 and calls for the modification of the selected parts (e.g. cutting or complete removal by laser ablation).

Element 391 follows element 366 or element 381 and calls for the release of at least part of the parts from the sacrificial material and possibly from the substrate. Element 392 follows element 391 and calls for the optional separation of the modified parts (i.e. bad parts) from the whole parts (i.e. good parts). Element 393 follows element 392 and calls for the putting of the whole parts to use such as assembling them with other components to make one or more devices.

The process 350 of FIG. 10 provides generalized steps for the fabrication of parts and the distinguishing of good parts from bad parts and the putting of the good parts to use. It is clear that many variations of the process are possible. Some variations might add additional steps, some variations might change the order of performing some steps, and some variations may remove some steps. The variations discussed above regard to the first or second embodiments, apply here mutatis mutandis. In still other variations, the protective coating of the second embodiment may also be used in this embodiment, either on the last layer or potentially on any intermediate layers where part modification is to occur.

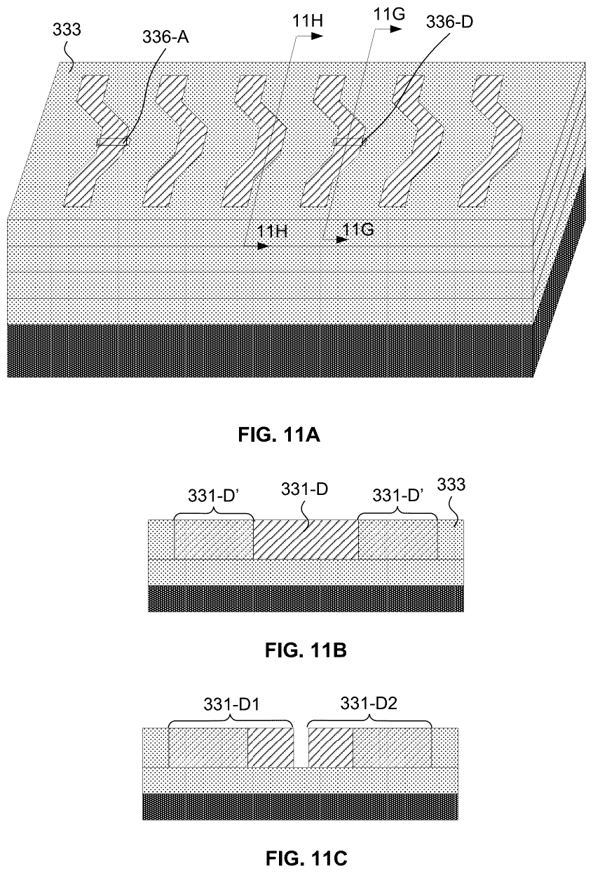

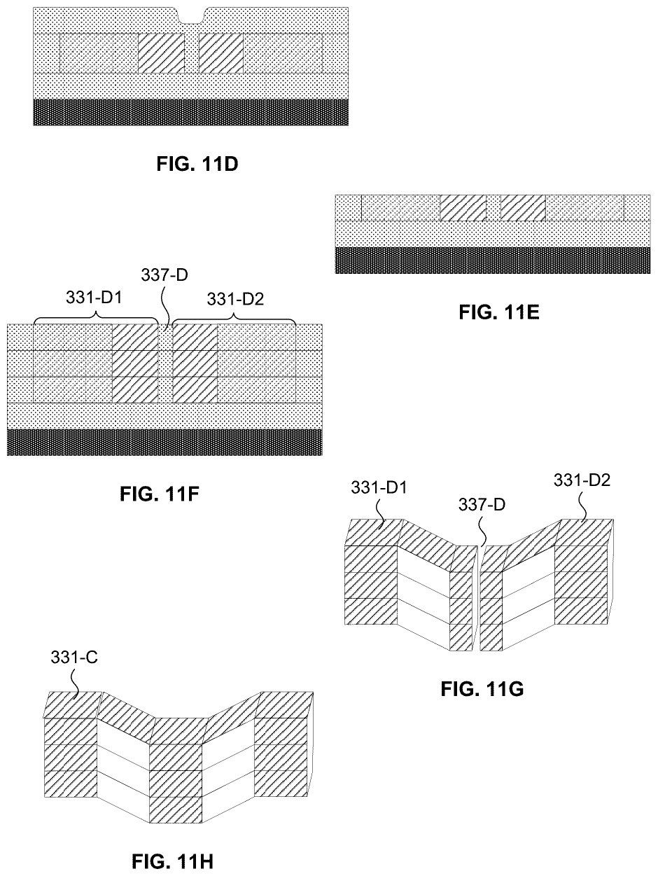

FIG. 11A provides a perspective view similar to that of FIG. 7E showing that the first and fourth parts from the left have been modified (e.g. cut through) where like features are designated with like reference numbers with the exception that the numbers have been incremented to the 300 series.

FIGS. 11B-11F show cut views from the perspective of pointers 11G-11G of FIG. 11A for various states of the process during formation of a sample layer (e.g. the first layer as illustrated) and in particular of a portion of the part that will be dissected according to the embodiment of FIG. 10.

FIG. 11B shows the state of the process after formation of a first layer where the formation of part 331-D has failed wherein part modification is required and will be performed on this first layer and possibly on subsequent layers as well. FIG. 11B shows clearly the structural material of part 331-D in the central region while showing buried portions 331-D′ of part 331-D hidden behind sacrificial material 333 on either side of 331-D. FIG. 11C shows the state of the process after modifying the central part of structure 331-D by cutting, ablation, punching, drilling, milling or the like such that on layer L1, part 331-D is cut into two distinct elements 331-D1 and 331-D2. FIG. 11D shows the state of the process after sacrificial material is deposited to fill the void created by the modification process while FIG. 11E shows the state of the process after the layer has been planarized to set the boundary level for the layer. As noted previously, the initial planarization resulting in the upper surface of the part of FIG. 11A may have set a level above the desired layer level such that the planarization of FIG. 11E could set an accurate layer level with the correct materials located at the various lateral positions of the upper surface of the layer. FIG. 11F shows the state of the process after formation of layers L2 and L3 including modifications that break failed part 331-D into pieces 331-D1 and 331-D2. The method of modifying layers L2 and L3 may be similar to that noted for layer L1.

FIG. 11G provides a perspective view of the dissected part 331-D showing both portions 331-D1 and 331-D2 from the view of pointers 11G-11G of FIG. 11A after release from the substrate and sacrificial material.

FIG. 11H provides a perspective view of the whole, or good, part 331-C from the view of pointers 11H-11H of FIG. 11A after release from the substrate and sacrificial material.

In view of the teachings herein, many further embodiments, alternatives in design and uses of the embodiments of the instant invention will be apparent to those of skill in the art. As such, it is not intended that the invention be limited to the particular illustrative embodiments, alternatives, and uses described above but instead that it be solely limited by the claims presented hereafter.

1. In a method for operating an electrochemical fabrication system to manufacture electronic test probe structures, of the type including:
(A) receiving parameter data for manufacturing the electronic test probe structures, wherein each probe structure has a compliant probe body of a first material and a contact tip made of a second material different from the first material;
(B) operating the electrochemical fabrication system based on the parameter data to: (i) deposit a structural material; (ii) deposit a conductive sacrificial material; and (iii) seize the deposited structural and sacrificial materials, to form a plurality of successive layers on a substrate in the electrochemical fabrication system, with, each successive layer adhered to a previously formed layer;
(C) after forming the successive layers, separating at least a portion of the conductive sacrificial material from the structural material to reveal the plurality of probe structures;
(D) with the plurality of probe structures on the substrate, comparing, by inspection or testing, a parameter of each probe structure to the parameter data;
(E) identifying probe structures on the substrate not compliant to the parameter data as being in a first group of probe structures and identifying probe structures compliant to the parameter data as being in a second group;
the improvement comprising:
(F) while the probe structures are on the substrate, adding a secondary material only to the probe structures in the first group;
(G) physically separating the first group of probe structures and the second group of probe structures from the substrate; and
(H) physically separating the first group of probe structures from the second group of probe structures using the secondary material.

2. The method of claim 1 further including assembling the probe structures in the second group with other components to create devices and scrapping the probe structures in the first group.

3. The method of claim 1 wherein the parameter data includes a mechanical and/or electrical property of the probe structures.

4. The method of claim 1 wherein the parameter data includes a limit on geometry distortion.

5. The method of claim 2 wherein probe structures missing any feature specified in the parameter data are identified as being in the first group.

6. The method of claim 1 wherein the secondary material is added by electroplating.

7. The method of claim 1 wherein the secondary material is a magnetic material.

8. The method of claim 7 wherein step H is performed using a magnet.

9. The method of claim 1 wherein the probe structures in the second group are formed of non-magnetic material.

10. The method of claim 1 wherein the secondary material comprises: a polymer, a photoresist, parylene, a curable monomer or oligomer, and/or a wax.

11. The method of claim 10 wherein the secondary material is coated with a hydrophobic material.

12. The method of claim 11 further including immersing the first and second groups of probe structures into a liquid, to separate them via a buoyancy differential.
